(19) United States
(12) Patent Application Publication
(10) Pub. No.: US 2017/0207605 A1
(43) Pub. Date: Jul. 20, 2017

(54) SEMICONDUCTOR LASER DEVICE

(71) Applicant: MITSUBISHI ELECTRIC CORPORATION, Chiyoda-ku (JP)

(72) Inventors: Daiji MORITA, Chiyoda-ku (JP); Masato KAWASAKI, Chiuoda-ku (JP); Susumu KONNO, Chiyoda-ku (JP); Tomotaka KATSURA, Chiyoda-ku (JP); Shuichi FUJIKAWA, Chiyoda-ku (JP)

(73) Assignee: MITSUBISHI ELECTRIC CORPORATION, Chiyoda-ku (JP)

(21) Appl. No.: 15/315,436

(22) PCT Filed: Jul. 24, 2015
(86) PCT No.: PCT/JP2015/071097

§ 371 Date: Dec. 1, 2016

(30) Foreign Application Priority Data
Jul. 25, 2014 (JP) 2014-151641

(51) Int. Cl. H01S 5/40; H01S 5/022; H01S 5/14

(52) U.S. Cl. CPC H01S 5/4012; H01S 5/143; H01S 5/4087; H01S 5/02288

(57) ABSTRACT

A semiconductor laser device, in which, between a wavelength dispersive element and a partially reflecting mirror, such an anamorphic prism pair is arranged that is configured to increase an angle formed by a regular oscillation optical axis of a regular oscillation beam emitted from each of light emitting points and a cross-coupling optical axis of a cross-coupling oscillation beam oscillating through a different one of the light emitting points. It is therefore possible to increase oscillation loss of the cross-coupling oscillation beam, thereby improving focusing properties, without increasing the device in size.

### TECHNICAL FIELD

The present invention relates to a semiconductor laser device configured to superimpose, by wavelength dispersion of a wavelength dispersive element, beams having a plurality of wavelengths generated from a plurality of light emitting points, and to output the superimposed beam.

### BACKGROUND ART

Such a semiconductor laser device has hitherto been known that includes a spatial filter arranged between a wavelength dispersive element and a partially reflecting mirror of an external laser resonator in order to suppress cross-coupling oscillation beam output due to optical paths of the external laser resonator that are formed by different light emitting points (for example, see Patent Literature 1 and Patent Literature 2).

### CITATION LIST

### Patent Literature

[PTL 1] U.S. Ser. No. 06/192,062 B2
[PTL 2] U.S. Ser. No. 07/065,107 B2

### SUMMARY OF INVENTION

### Technical Problem

However, the semiconductor laser device has a problem in that oscillation beams interfere with a slit used in the spatial filter, and laser output is thus lowered.

Further, in order to prevent the oscillation beams from interfering with the slit and to reduce the device in size, it is necessary to reduce focal lengths of lenses used in the spatial filter, resulting in a problem in that laser output and focusing properties are lowered due to aberration of the lenses.

In addition, there are problems in that the slit is liable to be burned during the slit adjustment because the slit is arranged at the focus positions of the lenses, and hence it is very difficult to adjust the slit, and that a cooling mechanism is needed for the slit in order to cope with burning of the slit, leading to high cost.

The present invention aims to solve the problems described above, and has an object to obtain a semiconductor laser device capable of increasing oscillation loss of cross-coupling oscillation beams, thereby improving focusing properties, without increasing the device in size.

### Solution to Problem

According to one embodiment of the present invention, there is provided a semiconductor laser device, including: an external laser resonator including: a wavelength dispersive element on which beams from a plurality of light emitting points are superimposed; and a partially reflecting mirror on which the beams having passed through the wavelength dispersive element radiate, and which is configured to output part of the beams to outside and reflect a remaining part of the beams, the external laser resonator being configured to superimpose, by wavelength dispersion of the wavelength dispersive element, the beams having a plurality of wavelengths generated from the plurality of light emitting points, and output to the outside a regular oscillation beam oscillated by each of the plurality of light emitting points; and an angle increasing element, which is arranged between the wavelength dispersive element and the partially reflecting mirror, and is configured to increase an angle formed by a regular oscillation optical axis being an optical axis of the regular oscillation beam, and a cross-coupling optical axis being an optical axis of a cross-coupling oscillation beam oscillating through a different one of the plurality of light emitting points.

### Advantageous Effects of Invention

According to the semiconductor laser device of the present invention, between the wavelength dispersive element and the partially reflecting mirror, such an angle increasing element is arranged that is configured to increase the angle formed by the regular oscillation optical axis of the regular oscillation beam emitted from each of the light emitting points and the cross-coupling optical axis of the cross-coupling oscillation beam oscillating through a different one of the light emitting points. It is therefore possible to increase oscillation loss of the cross-coupling oscillation beam, thereby improving the focusing properties, without increasing the device in size.

### BRIEF DESCRIPTION OF DRAWINGS

FIG. 1 is a schematic configuration diagram for illustrating a semiconductor laser device according to a first embodiment of the present invention.

FIG. 2 is a graph for showing spectra of a regular oscillation beam of the semiconductor laser device of FIG. 1.

FIG. 3 is a schematic configuration diagram for illustrating cross-coupling oscillation beams in the semiconductor laser device.

FIG. 4 is a graph for showing spectra of the cross-coupling oscillation beams.

FIG. 5 is a schematic configuration diagram for illustrating a method of suppressing the cross-coupling oscillation beams of the semiconductor laser device.

FIG. 6 is a schematic configuration diagram for illustrating an effect of suppressing the cross-coupling oscillation beams in the semiconductor laser device of FIG. 1.

FIG. 7 is a schematic configuration diagram for illustrating a semiconductor laser device according to a second embodiment of the present invention.

FIG. 8 is a schematic configuration diagram for illustrating a semiconductor laser device according to a third embodiment of the present invention.

### DESCRIPTION OF EMBODIMENTS

Now, embodiments of the present invention are described referring to the accompanying drawings. In the drawings, the same or corresponding parts are denoted by the same reference symbols for description.

### First Embodiment

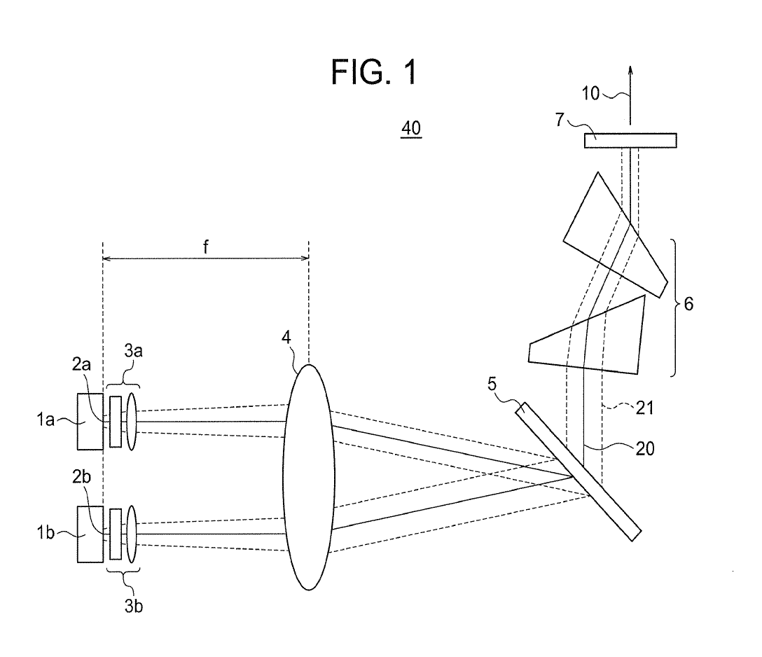

FIG. 1 is a schematic configuration diagram for illustrating a semiconductor laser device 40 according to a first embodiment of the present invention.

The semiconductor laser device 40 is configured to superimpose, into a single beam, light beams emitted from a first light emitting point 2a and a second light emitting point 2b of a first semiconductor laser 1a and a second semiconductor laser 1b, respectively, by using a wavelength dispersion effect of a wavelength dispersive element 5.

In the semiconductor laser device 40, as a laser resonator, an optical system is formed of optical elements between surfaces of the light emitting points 2a and 2b of the semiconductor lasers 1a and 1b, which are opposite to light emitting-side surfaces thereof, and a partially reflecting mirror 7. Further, in the semiconductor lasers 1a and 1b, in general, the light emitting points 2a and 2b themselves serve as laser resonators. In the following description, the above-mentioned laser resonator that is installed outside the light emitting points 2a and 2b, and includes the partially reflecting mirror 7 and the like as components is referred to as an external laser resonator.

For simplifying the illustration, in FIG. 1, there are illustrated two semiconductor lasers of the first semiconductor laser 1a and the second semiconductor laser 1b, and the light emitting points 2a and 2b are provided to the semiconductor lasers 1a and 1b, respectively (so-called single emitter semiconductor laser).

The number of light emitting points may be larger than the number of semiconductor lasers. Further, also in a case where a plurality of light emitting points are present on one semiconductor laser (so-called semiconductor laser bar), light beams from a plurality of light emitting points can be superimposed into a single beam by the wavelength dispersive element 5.

Although the beams reciprocate in the external laser resonator in actuality, there is first described propagation of the beams in a direction from the first light emitting point 2a and the second light emitting point 2b to the partially reflecting mirror 7.

The beams generated from the light emitting points 2a and 2b of the semiconductor lasers 1a and 1b are emitted while diverging. In order to couple the beams generated from the semiconductor lasers 1a and 1b to a mode of the external resonator, the beams are substantially collimated by beam collimating optical systems 3a and 3b.

As the beam collimating optical systems 3a and 3b, cylindrical lenses, spherical lenses, aspherical lenses, or mirrors having curvatures, or combinations thereof can be used.

In general, the light beams generated from the semiconductor lasers 1a and 1b have an anisotropic divergence angle, and thus have different divergence angles between a direction vertical to the drawing sheet and a direction in the drawing sheet. Hence, it is desired that, as the beam collimating optical systems 3a and 3b, a plurality of lenses or curvature mirrors be used in combination.

Further, in this case, the beam collimating optical systems 3a and 3b may include beam rotation optical systems.

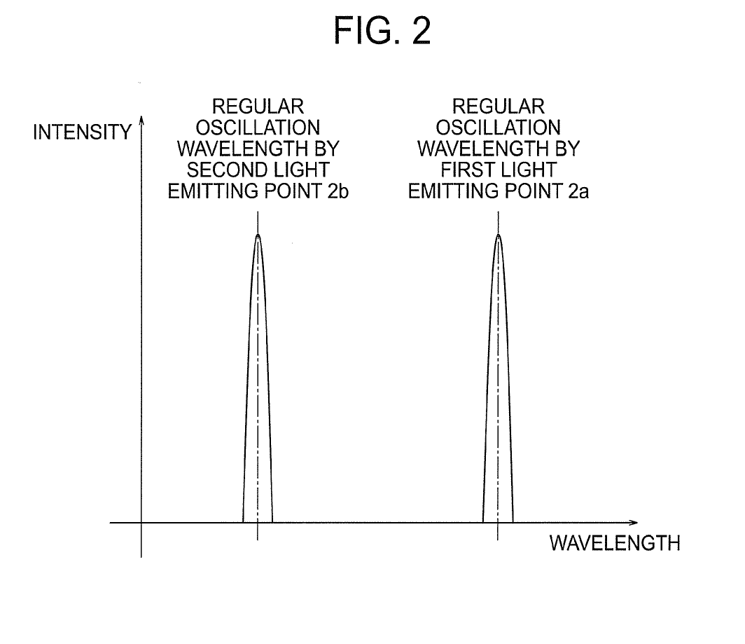

As the beam rotation optical system, a cylindrical lens array disclosed in a publication (see Japanese Patent Application Laid-open No. 2000-137139, FIG. 2), a reflection mirror disclosed in a publication (WO 98/08128), or the like is used.

Through the above-mentioned beam rotation optical systems, the anisotropic beams emitted from the light emitting points 2a and 2b are rotated by about 90° in a plane vertical to optical axes.

The beams substantially collimated by the beam collimating optical systems 3a and 3b are spatially overlapped with each other on the wavelength dispersive element 5 by a coupling optical system 4.

Although the coupling optical system 4 at a focal length f is illustrated as one lens in FIG. 1, as the coupling optical system 4, a cylindrical lens, a spherical lens, an aspherical lens, or a mirror having a curvature, or a combination thereof can be used.

As the wavelength dispersive element 5, a reflective diffraction grating, a transmissive diffraction grating, a prism, or an element (grism) combining a diffraction grating and a prism can be used. When wavelength dispersion is large, that is, when a difference in angle of diffraction or angle of refraction is large between emitted beams having two different wavelengths, the beams from the plurality of semiconductor lasers 1a and 1b can be superimposed in small space. Thus, it is desired that a diffraction grating be used rather than a prism.

When different light beams emitted from the first light emitting point 2a and the second light emitting point 2b have certain different wavelengths, the incident beams from the light emitting points 2a and 2b are superimposed into a single beam due to the wavelength dispersion of the wavelength dispersive element 5, that is, such characteristics that the angle of diffraction or the angle of refraction is changed depending on wavelength.

The single beam obtained through superimposition of the beams passes through an anamorphic prism pair 6 serving as an angle increasing element, and is then emitted to the partially reflecting mirror 7.

At this time, the anamorphic prism pair 6 is oriented such that, after the beam traveling from the wavelength dispersive element 5 to the partially reflecting mirror 7 passes through the anamorphic prism pair 6, only a regular oscillation output beam size 21 in an axis parallel to the drawing sheet is reduced.

The anamorphic prism pair 6 including two prisms can change the beam size only in one direction, and is often used for the purpose of shaping an ellipsoidal beam into a circular beam.

Part of the beam radiated on the partially reflecting mirror 7 is transmitted through the partially reflecting mirror 7 to be extracted as a regular oscillation output beam 10. The remaining part is reflected by the partially reflecting mirror 7.

The reflected beam propagates in the same path as the beam traveling from the first light emitting point 2a and the second light emitting point 2b to the partially reflecting mirror 7 in an opposite direction, enters the first light emitting point 2a of the first semiconductor laser 1a and the second light emitting point 2b of the second semiconductor laser 1b, and properly returns to rear-side end surfaces of the first light emitting point 2a of the first semiconductor laser 1a and the second light emitting point 2b of the second semiconductor laser 1b. In this way, a function as the external laser resonator is achieved.

In order to achieve the external laser resonator, positions and angles of the partially reflecting mirror 7, the wavelength dispersive element 5, the coupling optical system 4, and the beam collimating optical systems 3a and 3b are adjusted.

Under a state in which the external laser resonator is achieved, one optical axis is formed between the partially reflecting mirror 7 and the wavelength dispersive element 5, and two different optical axes are formed between the wavelength dispersive element 5 and the first light emitting point 2a and the second light emitting point 2b. The two different optical axes connect the wavelength dispersive element 5 and the first light emitting point 2a to each other, and connect the wavelength dispersive element 5 and the second light emitting point 2b to each other. Laser oscillation wavelengths by the first light emitting point 2a and the second light emitting point 2b are automatically determined such that those optical axes are formed.

That is, in the semiconductor laser device 40, when the function of the external laser resonator is achieved, the oscillation wavelengths of the first light emitting point 2a and the second light emitting point 2b are automatically determined such that the external laser resonator is achieved with a regular oscillation optical axis 20 being the one optical axis formed between the partially reflecting mirror 7 and the wavelength dispersive element 5 in FIG. 1. The wavelengths are different from each other.

In the following, this oscillation beam is referred to as a regular oscillation beam.

In FIG. 2, wavelength spectra during emission of the regular oscillation beam are shown.

In this regular oscillation beam, two beams from the first light emitting point 2a and the second light emitting point 2b are superimposed and emitted from the partially reflecting mirror 7 as the single regular oscillation output beam 10. Thus, the luminance can be approximately doubled. The luminance can further be improved when the number of semiconductor lasers and the number of light emitting points are increased.

Meanwhile, even when the optical elements in the external laser resonator are adjusted such that the regular oscillation optical axis 20 of FIG. 1 is formed, undesired laser oscillation may occur.

As described later, laser beams each undesirably oscillate through a different one of the first light emitting point 2a and the second light emitting point 2b. In the following, this undesired laser oscillation beam is referred to as a cross-coupling oscillation beam.

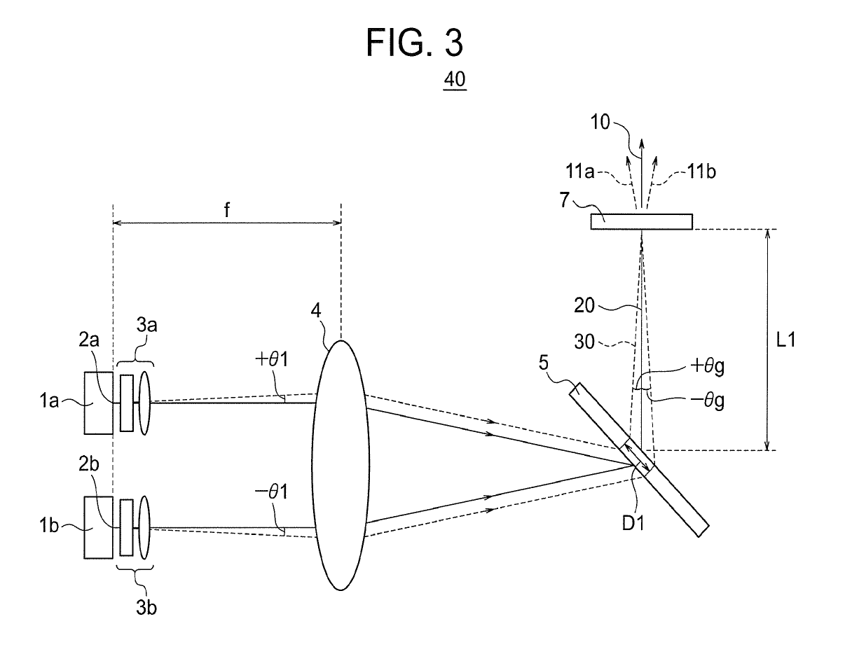

Next, the cross-coupling oscillation beams are described with reference to FIG. 3.

In FIG. 3, in order to simplify description of the cross-coupling oscillation beams, the semiconductor laser device includes the minimum number of optical elements, and the anamorphic prism pair 6, which is illustrated in FIG. 1, is not arranged between the wavelength dispersive element 5 and the partially reflecting mirror 7.

In FIG. 3, cross-coupling optical axes 30 being optical axes of the cross-coupling oscillation beams are indicated by the dotted lines and the regular oscillation optical axis 20 is indicated by the solid line.

The regular oscillation optical axis 20 is at one point on the wavelength dispersive element 5 and vertically enters the partially reflecting mirror 7.

On the other hand, the cross-coupling optical axes 30 do not focus on one point on the wavelength dispersive element 5, and enter the partially reflecting mirror 7 not vertically but obliquely.

The cross-coupling optical axes 30 are obliquely incident on and emitted from the first light emitting point 2a and the second light emitting point 2b. The beams may be generated from the first light emitting point 2a and the second light emitting point 2b with certain angular widths, and hence even with the cross-coupling optical axes 30 of the cross-coupling oscillation beams, which are the beams oblique to the first light emitting point 2a and the second light emitting point 2b, the external laser resonator is achieved.

At this time, part of the beam emitted from the first light emitting point 2a is specularly reflected by the partially reflecting mirror 7, and then enters the second light emitting point 2b. Part of the beam emitted from the second light emitting point 2b is specularly reflected by the partially reflecting mirror 7, and then enters the first light emitting point 2a.

In this way, the external laser resonator is achieved with the optical paths in which the beams are incident on and emitted from the first light emitting point 2a and the second light emitting point 2b in a reciprocation manner.

At this time, the regular oscillation optical axis 20 is vertical to the partially reflecting mirror 7 and is one optical axis, whereas the cross-coupling optical axes 30 are oblique to the partially reflecting mirror 7 as illustrated in FIG. 3.

Consequently, in addition to the regular oscillation output beam 10 generated from the regular oscillation optical axis 20, cross-coupling oscillate output beams 11a and 11b having different traveling directions are mixed to lower the focusing properties of the beam generated from the external laser resonator.

Now, prior to detail description of the cross-coupling optical axes 30, the following two conditions are provided.

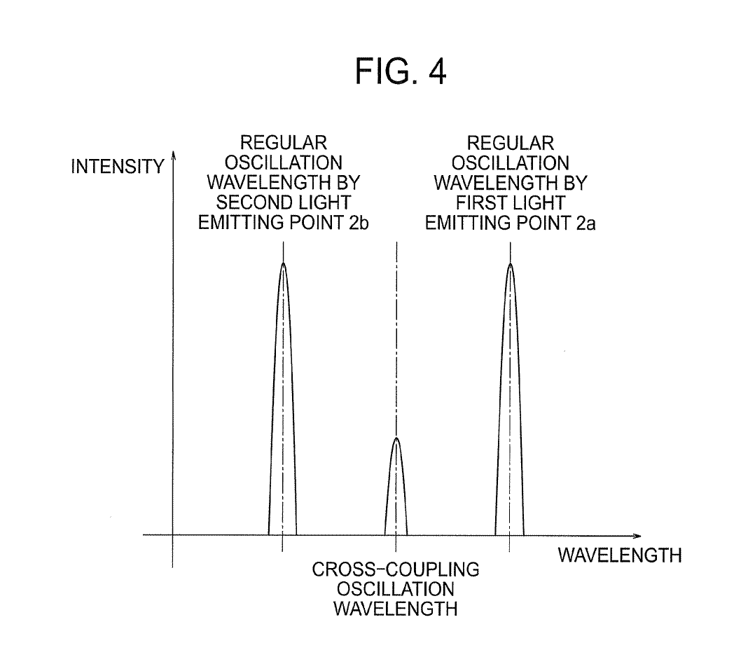

Condition 1 is that, as shown in FIG. 4, an oscillation wavelength due to cross-coupling is an intermediate wavelength between oscillation wavelengths of the first light emitting point 2a and the second light emitting point 2b during the emission of the regular oscillation beam.

Condition 2 is that, as illustrated in FIG. 3, emission angles of the cross-coupling optical axes 30 emitted from the first light emitting point 2a and the second light emitting point 2b are vertically symmetrical with respect to the regular oscillation optical axis 20.

The conditions provided above are used in order to make the description easy to understand, and cross-coupling oscillation beams under other conditions than the above-mentioned conditions are conceivable in actuality. However, the cross-coupling oscillation beams are satisfactorily understood with the above-mentioned conditions.

Based on Condition 2, the emission angles of the cross-coupling optical axes 30 of the cross-coupling oscillation beams emitted from the first light emitting point 2a and the second light emitting point 2b illustrated in FIG. 3 are +θ1 and −θ1, respectively. Based on Condition 1, the cross-coupling optical axes 30 extend at angles of +θg and −θg, respectively, after passing through the wavelength dispersive element 5, and intersect with the regular oscillation optical axis 20 on the partially reflecting mirror 7.

Part of the cross-coupling optical axes 30 of the cross-coupling oscillation beams entering the partially reflecting mirror 7 is specularly reflected. Among the specularly reflected beams, the cross-coupling optical axis 30 emitted from the first light emitting point 2a enters the second light emitting point 2b, and the cross-coupling optical axis 30 emitted from the second light emitting point 2b enters the first light emitting point 2a. In this way, cross-coupling oscillation beam optical paths are formed.

Next, a method of suppressing the cross-coupling oscillation beams is described.

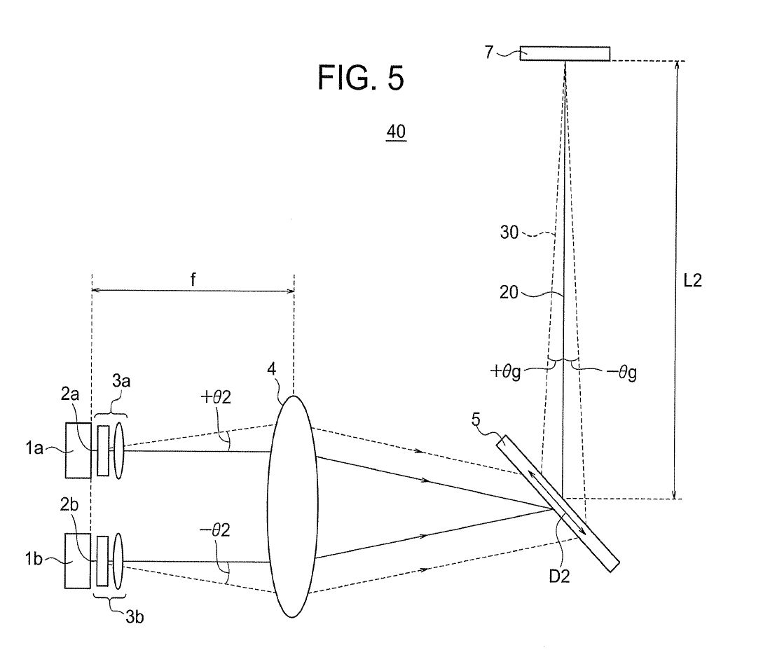

In FIG. 3, a distance from the wavelength dispersive element 5 to the partially reflecting mirror 7 is set to L1. This distance is set to L2(>L1) as illustrated in FIG. 5. At this time, the wavelengths of the cross-coupling oscillation beams are not changed based on Condition 1, and hence angles formed by the cross-coupling optical axes 30 and the regular oscillation optical axis 20 between the wavelength dispersive element 5 and the partially reflecting mirror 7 remain at +θg and −θg, respectively, which are the same as those of FIG. 3.

Consequently, a deviation amount of the cross-coupling optical axes 30 from the regular oscillation optical axis 20 on the wavelength dispersive element 5 is D1 in the configuration of FIG. 3, and is D2=(L2/L1)×D1 in the configuration of FIG. 5. D2 has a larger value than D1.

As a result, the emission angles of the cross-coupling optical axes 30 of the cross-coupling oscillation beams emitted from the first light emitting point 2a and the second light emitting point 2b are angles of +θ2 and −θ2, respectively, with respect to the regular oscillation optical axis 20.

At this time, θ2=(L2/L1)×θ1 and θ2>θ1 are satisfied.

It is conceivable that as the angles formed by the cross-coupling optical axes 30 of the cross-coupling oscillation beams emitted from the first light emitting point 2a and the second light emitting point 2b and the regular oscillation optical axis 20 are increased, resonation of the cross-coupling oscillation beams at the light emitting points 2a and 2b is suppressed, and oscillation loss of the cross-coupling oscillation beams is increased. Thus, the cross-coupling oscillation beams can be suppressed by increasing the value of the angles θ2 formed by the cross-coupling optical axes 30 and the regular oscillation optical axis 20 of FIG. 5.

From the above description, it is found that in order to suppress the cross-coupling oscillation beams, it is effective to increase the above-mentioned angles θ2, that is, to increase the deviation amount of the cross-coupling optical axes 30 from the regular oscillation optical axis 20 on the wavelength dispersive element 5.

However, θg is a significantly small value in general, and hence L2 needs to be significantly increased in order to increase D2 to a value enabling suppression of the cross-coupling oscillation beams, resulting in a problem in that the device is greatly increased in size.

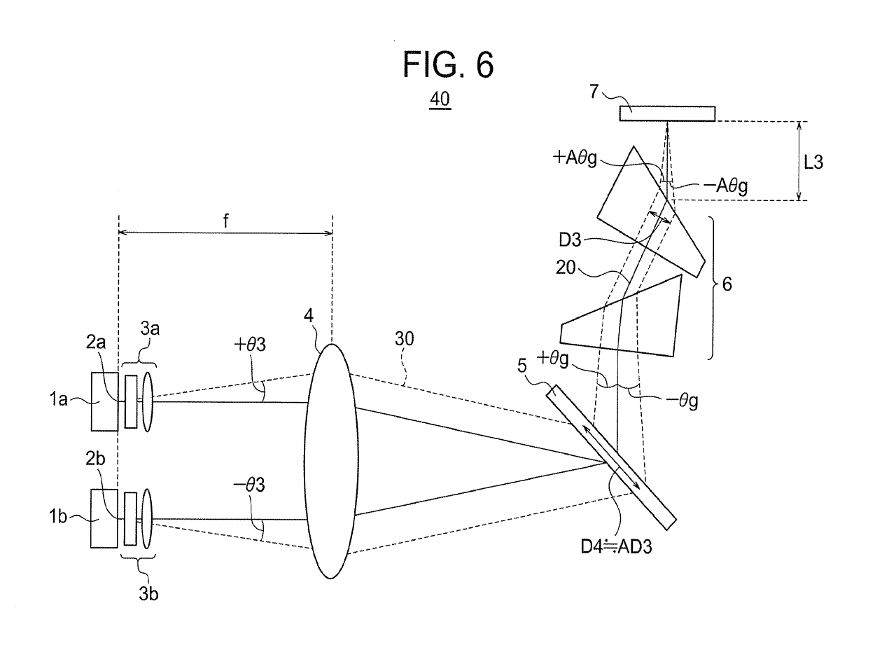

Meanwhile, the semiconductor laser device 40 of the first embodiment is configured to suppress the cross-coupling oscillation beams without greatly increasing the device in size. Now, an effect of suppressing the cross-coupling oscillation beams is described with reference to FIG. 6.

In FIG. 6, the anamorphic prism pair 6 has an effect of reducing the size of a beam in an axis parallel to the drawing sheet by 1/A times when the beam passes through the anamorphic prism pair 6 in a direction toward the light emitting points 2a and 2b, which is an emission direction of the beam. Here, A is a natural number other than 0, and the value of A can be freely selected by adjusting the arrangement and shape of the anamorphic prism pair 6. Commercially supplied anamorphic prism pairs have A of about 2 to 6 in many cases.

At this time, with regard to the angles of the optical axes, when angles formed by the cross-coupling optical axes 30 and the regular oscillation optical axis 20 between the wavelength dispersive element 5 and the anamorphic prism pair 6 are +θg and −θg, respectively, angles formed by the cross-coupling optical axes and the regular oscillation optical axis 20 between the anamorphic prism pair 6 and the partially reflecting mirror 7 are +Aθg and −Aθg, respectively, which are A times as large as +θg and −θg in the drawing sheet. At this time, the deviation amount D4 of the cross-coupling optical axes 30 from the regular oscillation optical axis 20 on the wavelength dispersive element 5 has sufficiently small θg, and hence D4≈AD3 is satisfied.

It is found that while it is effective to increase the above-mentioned deviation amount D4 in order to suppress the cross-coupling oscillation beams as described above, D3 only needs to be increased instead in the semiconductor laser device 40 of the first embodiment. L3 only needs to be increased in order to increase D3.

At this time, the angle formed by the cross-coupling optical axes 30 and the regular oscillation optical axis 20 between the anamorphic prism pair 6 and the partially reflecting mirror 7 are +Aθg and −Aθg, respectively. The angles formed by the cross-coupling optical axes 30 and the regular oscillation optical axis 20 are increased by A times, and hence an amount of increase in D3 along with an increase in L3 is also increased by A times.

Here, there is considered a case of obtaining, with the use of the semiconductor laser device 40 of the first embodiment illustrated in FIG. 6, an effect of suppressing the cross-coupling oscillation beams equivalent to that of the configuration illustrated in FIG. 5 in which the distance from the wavelength dispersive element 5 to the partially reflecting mirror 7 is set to L2.

In order to obtain the effect of suppressing the cross-coupling oscillation beams equivalent to that of FIG. 5, D4=AD3=D2 only needs to be satisfied. Accordingly, a value of L3 with which D3=D2/A is satisfied is determined.

Values of D3 and D2 are determined based on Expressions (1) and (2).

D3≈Aθg×L3 (1)

D2=θg×L2 (2)

L3 is determined from Expression (1).

L3=D3/Aθg (3)

Now, D3=D2/A is satisfied, and hence Expression (3) is transformed as follows.

L3=D2/Aθg (4)

The following is satisfied when Expression (2) is substituted into Expression (4).

L3=L2/A2 (5)

Through the calculation above, it is found that L3=L2/A2 only needs to be satisfied in order to satisfy D3=D2/A.

As described above, according to the semiconductor laser device 40 of the first embodiment, between the wavelength dispersive element 5 and the partially reflecting mirror 7, such an anamorphic prism pair 6 is arranged that serves as the angle increasing element configured to increase the angles formed by the regular oscillation optical axis 20 of the regular oscillation beam, which is emitted from each of the light emitting points 2a and 2b, and the cross-coupling optical axes 30 of the cross-coupling oscillation beams, each of which oscillates through a different one of the light emitting points 2a and 2b. There are therefore provided remarkable effects of achieving efficient suppression of the cross-coupling oscillation beams, thereby improving the focusing properties while maintaining the distance between the wavelength dispersive element 5 and the partially reflecting mirror 7 to be small, without using a spatial filter causing output reduction due to aberration of lenses or interference of beams with a shielding element.

### Second Embodiment

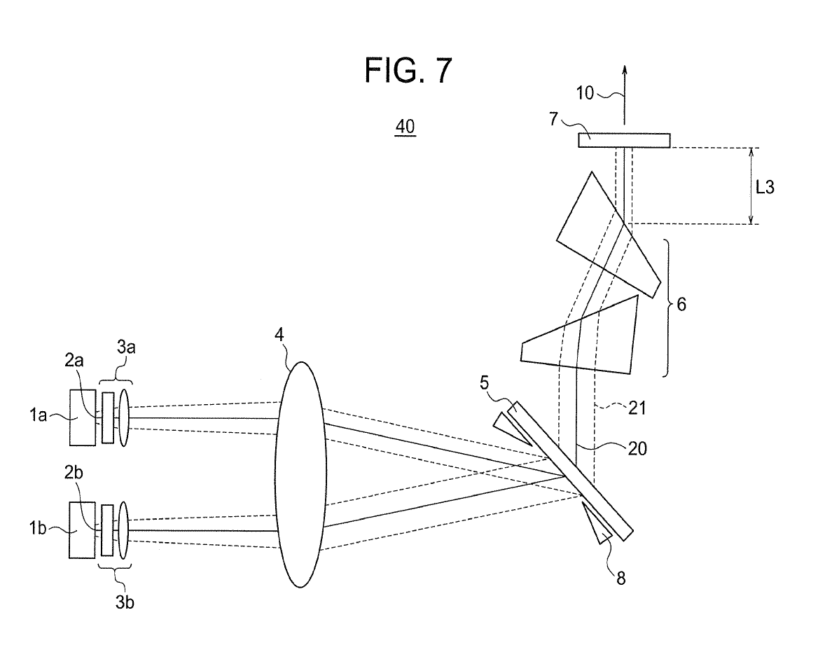

FIG. 7 is a schematic configuration diagram for illustrating the semiconductor laser device 40 according to a second embodiment of the present invention.

The semiconductor laser device 40 of the second embodiment is the semiconductor laser device 40 of the first embodiment to which an aperture 8 is added near the wavelength dispersive element 5. With the aperture 8, the cross-coupling oscillation beams are physically blocked.

The aperture width of the aperture 8 is larger than the regular oscillation output beam size 21 of the regular oscillation optical axis 20, and the aperture 8 is arranged so as not to interfere with the regular oscillation output beam 10. A rough indication of the aperture width of the aperture 8 is more than 1.1 times as large as the width of the regular oscillation output beam 10 in which 99% of all energy of the regular oscillation output beam 10 is included.

Even though the aperture width of the aperture 8 is large as described above, the deviation amount of the cross-coupling optical axes 30 from the regular oscillation optical axis 20 is large in the semiconductor laser device 40 of the second embodiment as in the semiconductor laser device 40 of the first embodiment, and hence the cross-coupling oscillation beams can be blocked effectively even with the use of such an aperture 8 with a large aperture width.

Further, the aperture 8 may not be arranged at a position near the wavelength dispersive element 5, but may be arranged near the coupling optical system 4. In short, it is only necessary that the aperture 8 be arranged at a position between the coupling optical system 4 and the wavelength dispersive element 5, at which the aperture 8 can effectively suppress the cross-coupling oscillation beams.

The remaining configuration is the same as that of the semiconductor laser device 40 of the first embodiment.

According to the semiconductor laser device 40 of the second embodiment, the aperture 8 is arranged between the coupling optical system 4 and the wavelength dispersive element 5, which are components of the external laser resonator, and hence the effect of suppressing the cross-coupling oscillation beams can always be maintained at a certain level without being affected by individual differences of the light emitting points 2a and 2b, such as allowable angular widths.

Further, cross-coupling oscillation beams not exceeding the allowable angular widths of the light emitting points 2a and 2b can also be blocked, and hence the distance L3 between the partially reflecting mirror 7 and the anamorphic prism pair 6 can further be shortened, thereby enabling further reduction of the device in size.

Although the anamorphic prism pair 6 is used as the angle increasing element in the description of the semiconductor laser device 40 of each embodiment described above, as a matter of course, the angle increasing element is not limited thereto and may be another element as long as the element has the same function.

Further, although the semiconductor laser device of the first and second embodiments is described as the semiconductor laser device in which the coupling optical system 4, which is configured to superimpose the beams from the light emitting points 2a and 2b on the wavelength dispersive element 5, is arranged between the light emitting points 2a and 2b and the wavelength dispersive element 5, the present invention is also applicable to a semiconductor laser device in which the beams from the light emitting points 2a and 2b are directly superimposed on the wavelength dispersive element 5.

Further, the aperture 8 may be arranged at other positions than the position between the coupling optical system 4 and the wavelength dispersive element 5, such as a position on the light emitting point (2a, 2b) side of the coupling optical system 4 or a position on the anamorphic prism pair 6 side of the wavelength dispersive element 5. Further, the aperture 8 may be arranged at each position instead of being arranged at one position.

### Third Embodiment

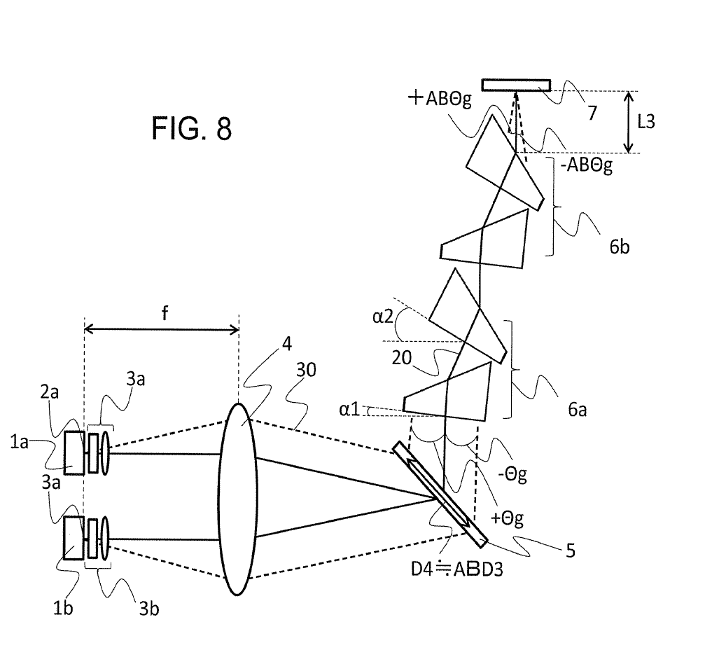

FIG. 8 is a schematic configuration diagram for illustrating the semiconductor laser device 40 according to a third embodiment of the present invention.

In the semiconductor laser device 40 of the third embodiment, to which one anamorphic prism pair is added compared to the semiconductor laser device 40 of the first embodiment, a first anamorphic prism pair 6a and a second anamorphic prism pair 6b are arranged between the wavelength dispersive element 5 and the partially reflecting mirror 7. In FIG. 8, the cross-coupling optical axes 30 in the anamorphic prism pairs 6a and 6b are omitted.

An angle increasing ratio of the added second anamorphic prism pair 6b is represented by B. Then, the deviation amount D4 of the cross-coupling optical axes 30 from the regular oscillation optical axis 20 on the wavelength dispersive element 5 is D4≈A×B×D3 when a distance between the second anamorphic prism pair 6b and the partially reflecting mirror 7 is set to L3.

It is effective to increase the above-mentioned deviation amount D4 in order to suppress the cross-coupling oscillation beams, and hence the semiconductor laser device 40 of the third embodiment exhibits an effect of suppressing the cross-coupling oscillation beams, which is stronger than those described above.

When the distance between the first semiconductor laser 1a and the second semiconductor laser 1b is shortened, the traveling angle θg of the cross-coupling optical axes 30 after passing through the wavelength dispersive element 5 is reduced. Thus, it is difficult to suppress the cross-coupling oscillation beams.

In this case, it is effective to increase an angle increasing ratio of the anamorphic prism pair 6 in order to suppress the cross-coupling oscillation beams. An angle α2 illustrated in FIG. 8 only needs to be increased in order to increase the angle increasing ratio of the anamorphic prism pair 6. However, when α2 is increased, loss due to reflection is increased to lower the oscillation efficiency.

Meanwhile, with the use of the semiconductor laser device 40 of the third embodiment, an effect of suppressing the cross-coupling can be enhanced without increasing angle increasing ratios of the respective anamorphic prism pairs 6a and 6b, thereby enabling reduction in oscillation loss.

According to the semiconductor laser device 40 of the third embodiment, the plurality of anamorphic prism pairs 6a and 6b are arranged so that the effect of suppressing the cross-coupling oscillation beams can be enhanced without increasing the oscillation loss.

Although two anamorphic prism pairs 6a and 6b are arranged in the semiconductor laser device 40 of the third embodiment, as a matter of course, the number of anamorphic prism pairs is not limited to two and may be three or more.

### REFERENCE SIGNS LIST

1a first semiconductor laser, 1b second semiconductor laser, 2a first light emitting point, 2b second light emitting point, 3 beam collimating optical system, 4 coupling optical system, 5 wavelength dispersive element, 6 anamorphic prism pair (angle increasing element), 6a first anamorphic prism pair (angle increasing element), 6b second anamorphic prism pair (angle increasing element), 7 partially reflecting mirror, 10 regular oscillation output beam, 11 cross-coupling oscillate output beam, 20 regular oscillation optical axis, 21 regular oscillation output beam size, 30 cross-coupling optical axis, semiconductor laser device

1. A semiconductor laser device, comprising:
an external laser resonator comprising:
a wavelength dispersive element on which beams from a plurality of light emitting points are superimposed; and
a partially reflecting mirror on which the beams having passed through the wavelength dispersive element radiate, and which is configured to output part of the beams to outside and reflect a remaining part of the beams,
the external laser resonator being configured to superimpose, by wavelength dispersion of the wavelength dispersive element, the beams having a plurality of wavelengths generated from the plurality of light emitting points, and output to the outside a regular oscillation beam oscillated by each of the plurality of light emitting points; and
an angle increasing element, which is arranged between the wavelength dispersive element and the partially reflecting mirror, and is configured to increase an angle formed by a regular oscillation optical axis being an optical axis of the regular oscillation beam, and a cross-coupling optical axis being an optical axis of a cross-coupling oscillation beam oscillating through a different one of the plurality of light emitting points.

2. The semiconductor laser device according to claim 1, further comprising one or a plurality of angle increasing elements arranged between the angle increasing element and the partially reflecting mirror.

3. The semiconductor laser device according to claim 1, wherein the angle increasing element comprises an anamorphic prism pair.

4. The semiconductor laser device according to claim 1, further comprising a coupling optical system arranged between the plurality of light emitting points and the wavelength dispersive element, the coupling optical system being configured to superimpose the beams from the plurality of light emitting points on the wavelength dispersive element.

5. The semiconductor laser device according to claim 4, further comprising an aperture configured to block the cross-coupling oscillation beam from entering to the wavelength dispersive element, the aperture being arranged at at least one of a position between the coupling optical system and the plurality of light emitting points, a position between the wavelength dispersive element and the angle increasing element, and a position between the coupling optical system and the wavelength dispersive element.

6. The semiconductor laser device according to claim 5, wherein an aperture width of the aperture is larger than a beam size of the regular oscillation beam.
